(19) United States
(12) Patent Application Publication
(10) Pub. No.: US 2025/0370287 A1
(43) Pub. Date: Dec. 4, 2025

(54) TRANSPARENT DISPLAY SUPPORTING A TWO-WAY VIEWING ANGLE

(71) Applicant: QUALCOMM Incorporated, San Diego, CA (US)

(72) Inventors: Francis JOSEPH, Thrissur (IN); Rejitha RAJENDRAN, Alappey (IN); Sigu JOSEPH, Hyderabad (IN)

(21) Appl. No.: 18/733,500

(22) Filed: Jun. 4, 2024

(51) Int. Cl. G02F 1/13; G02F 1/1334

(52) U.S. Cl. CPC G02F 1/1323; G02F 1/1334

(57) ABSTRACT

This disclosure provides systems, methods, and apparatuses for transparent displays that support two-way viewing angles. A transparent display may include one or more organic light-emitting diode (OLED) pixels configured for directional display in multiple directions. The pixel configuration may include an OLED, a set of switchable mirrors converging at an angle and configured to reflect an emission from the OLED, and a polymer dispersed liquid crystal (PDLC) material bisecting the angle between the set of switchable mirrors. The pixel configuration may display a first color in a first direction in accordance with the set of switchable mirrors being in a transparent state and the PDLC material being in an opaque state. The pixel configuration may additionally display a second color in a second direction in accordance with the set of switchable mirrors being in a mirrored state and the PDLC material being in a second transparent state.

### TECHNICAL FIELD

This disclosure relates generally to visual display technology and, more specifically, to transparent displays that support multiple viewing angles.

### DESCRIPTION OF THE RELATED TECHNOLOGY

In some systems, devices may include screens that can display images to users operating the devices. For example, a device may include a user interface which displays information to a user, receives inputs from the user, or both. Some devices may include transparent displays. A transparent display may include a screen that allows a user to see through the screen, while also displaying an image on the screen. The screen may include a set of pixels, where a pixel may display one color at a time. By displaying colors via the set of pixels, the screen can display an image to the user. Some examples of devices that may use transparent displays include augmented reality (AR) or extended reality (XR) glasses, wearable devices, tablet devices, cameras and camera view displays, gaming consoles, cockpit controls, electronic billboards or signs, architectural structures, appliances, smart windows, smart desk dividers, smart televisions, windshields or other windows of vehicles, or any combination thereof.

### SUMMARY

The systems, methods, and devices of this disclosure each have several innovative aspects, no single one of which is solely responsible for the desirable attributes disclosed herein.

One innovative aspect of the subject matter described in this disclosure can be implemented in a device. The device may include a processing system that includes processor circuitry and memory circuitry that stores code. The processing system may be configured to cause the device to display a first color in a first direction in accordance with a first emission of an organic light-emitting diode (OLED) in the first direction, a set of switchable mirrors being in a first transparent state, and a polymer dispersed liquid crystal (PDLC) material being in an opaque state. The processing system may be further configured to cause the device to display a second color in a second direction different from the first direction in accordance with a second emission of the OLED in the first direction and a reflection of the second emission according to the set of switchable mirrors being in a mirrored state and the PDLC material being in a second transparent state.

Another innovative aspect of the subject matter described in this disclosure can be implemented in a method. The method may include displaying a first color in a first direction in accordance with a first emission of an OLED in the first direction, a set of switchable mirrors being in a first transparent state, and a PDLC material being in an opaque state. The method may further include displaying a second color in a second direction different from the first direction in accordance with a second emission of the OLED in the first direction and a reflection of the second emission according to the set of switchable mirrors being in a mirrored state and the PDLC material being in a second transparent state.

Another innovative aspect of the subject matter described in this disclosure can be implemented in an apparatus. The apparatus may include means for displaying a first color in a first direction in accordance with a first emission of an OLED in the first direction, a set of switchable mirrors being in a first transparent state, and a PDLC material being in an opaque state. The apparatus may further include means for displaying a second color in a second direction different from the first direction in accordance with a second emission of the OLED in the first direction and a reflection of the second emission according to the set of switchable mirrors being in a mirrored state and the PDLC material being in a second transparent state.

Another innovative aspect of the subject matter described in this disclosure can be implemented in a non-transitory computer-readable medium storing code. The code may include instructions executable by one or more processors to display a first color in a first direction in accordance with a first emission of an OLED in the first direction, a set of switchable mirrors being in a first transparent state, and a PDLC material being in an opaque state. The code may include instructions further executable by the one or more processors to display a second color in a second direction different from the first direction in accordance with a second emission of the OLED in the first direction and a reflection of the second emission according to the set of switchable mirrors being in a mirrored state and the PDLC material being in a second transparent state.

In some implementations of the devices, methods, apparatuses, and non-transitory computer-readable mediums, the set of switchable mirrors switches between the first transparent state and the mirrored state according to a display frequency, and the PDLC material switches between the opaque state and the second transparent state according to the display frequency.

In some implementations of the devices, methods, apparatuses, and non-transitory computer-readable mediums, the set of switchable mirrors includes a first switchable mirror and a second switchable mirror, and the PDLC material may be located between the first switchable mirror and the second switchable mirror.

Another innovative aspect of the subject matter described in this disclosure can be implemented in a pixel structure. The pixel structure may include a first substrate parallel to a second substrate and an OLED between the first substrate and the second substrate and oriented for display in a first direction towards the second substrate. The pixel structure may further include a first switchable mirror oriented at a first angle to the OLED and extending in the first direction and a second switchable mirror oriented at a second angle to the first substrate and extending in the first direction, where the first switchable mirror and the second switchable mirror converge at a third angle. The pixel structure may further include a PDLC material oriented perpendicular to the OLED and extending in the first direction, where the PDLC material bisects the third angle between the first switchable mirror and the second switchable mirror.

In some implementations, the pixel structure may further include a shared conductive line coupled with the first switchable mirror, the second switchable mirror, and the PDLC material. In some other implementations, the pixel structure may further include a first conductive line coupled with the first switchable mirror and the second switchable mirror and a second conductive line coupled with the PDLC material.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an example of a wireless communications system that supports transparent displays with two-way viewing angles.

FIG. 2 shows an example of a pixel configuration that supports a transparent display with a two-way viewing angle.

FIGS. 3A, 3B and 3C show examples of different operational states for materials that support transparent displays with two-way viewing angles.

FIGS. 4A and 4B show examples of display configurations for directional displays.

FIG. 5 shows an example use case for a transparent display with a two-way viewing angle.

FIG. 6 shows an example of a process flow that supports a transparent display with a two-way viewing angle.

FIG. 7 shows a block diagram of an example display manager that supports a transparent display with a two-way viewing angle.

FIG. 8 shows a diagram of a system including an example device that supports a transparent display with a two-way viewing angle.

FIG. 9 shows a flowchart illustrating a method that supports a transparent display with a two-way viewing angle.

Like reference numbers and designations in the various drawings indicate like elements.

### DETAILED DESCRIPTION

The following description is directed to some implementations for the purposes of describing the innovative aspects of this disclosure. However, a person having ordinary skill in the art will readily recognize that the teachings herein can be applied in a multitude of different ways. The described implementations may be implemented in any device, system, or network that is capable of transmitting and receiving radio frequency (RF) signals according to any of the Institute of Electrical and Electronics Engineers (IEEE) 16.11 standards, or any of the IEEE 802.11 standards, the Bluetooth® standard, code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless, cellular or internet of things (IOT) network, such as a system utilizing third generation (3G), fourth generation (4G), fifth generation (5G), or sixth generation (6G), or further implementations thereof, technology.

Various aspects relate generally to a pixel configuration for a transparent display that supports displaying content in multiple directions. Some aspects more specifically relate to concurrently displaying different contents in different directions using a same organic light-emitting diode (OLED) of the transparent display. The transparent display may include one or more pixels configured for two-way viewing angles. A pixel configuration of the transparent display may include an OLED between two substrates and oriented for display in a first direction. The OLED may be formed on a first substrate and oriented to display towards the second substrate. The pixel configuration may further include a first switchable mirror oriented at a first angle to the OLED and a second switchable mirror oriented at a second angle to the first substrate, where the first and second switchable mirrors converge at a third angle. A switchable mirror may be an example of a liquid crystal material that may reflect light or allow light to pass through the material according to an electric current applied to the switchable mirror. The switchable mirror may reflect the light while operating in a “mirrored” state and may allow the light to pass through while operating in a “transparent” state. The pixel configuration may additionally include a polymer dispersed liquid crystal (PDLC) material bisecting the third angle between the first and second switchable mirrors. The PDLC material may scatter light or allow light to pass through the material according to an electric current applied to the PDLC material. The PDLC material may scatter the light while operating in an “opaque” state and may allow the light to pass through while operating in a “transparent” state.

The transparent display may switch the states of the switchable mirrors and the PDLC material to switch between displaying different contents in different directions. If the transparent display switches the states according to a display frequency that satisfies a threshold frequency (such as greater than or equal to 30 Hertz (Hz)), to a human eye, the contents displayed in each direction may appear to be displayed constantly, despite the transparent display switching between displaying first content in a first direction and second content in a second direction in accordance with the display frequency. That is, at a high enough frequency (such as a frequency satisfying the threshold frequency), the human eye may fail to detect the contents switching between being displayed and not being displayed in one direction, and instead may interpret the contents as being constantly displayed in this direction. If the transparent display switches between displaying the first contents in the first direction and the second contents in the second direction according to such a frequency, the transparent display may appear, to the human eye, to concurrently display the different contents in the different directions, for example, via different sides of a transparent or semi-transparent screen. A pixel of the transparent display may display a first color in a first direction in accordance with a first emission of the OLED in the first direction. The first emission may pass through a first switchable mirror of the set of switchable mirrors in accordance with the switchable mirrors being in the transparent state and the PDLC material being in the opaque state. The pixel may further display a second color in a second direction in accordance with a second emission of the OLED in the first direction. The second emission may reflect off the first switchable mirror, pass through the PDLC material, and reflect off a second switchable mirror in the second direction in accordance with the set of switchable mirrors being in the mirrored state and the PDLC material being in the transparent state.

Particular implementations of the subject matter described in this disclosure can be implemented to realize one or more of the following potential advantages. By using the set of switchable mirrors, an emission from a unidirectional OLED (such as a top-emitting OLED or a bottom-emitting OLED) may be displayed in different directions according to current states of the switchable mirrors. By switching the states of the switchable mirrors and the PDLC material, the transparent display may display different contents in different directions. Viewers on either side of the transparent display may view different contents without either of the viewers seeing a mirror image of the contents displayed to the other viewer. Additionally, or alternatively, by switching the states of the switchable mirrors and the PDLC material according to the display frequency that satisfies the threshold frequency (such as greater than or equal to 30 Hz), the switching may be imperceptible to the human eye and, accordingly, the contents displayed in the different directions may appear to be displayed concurrently to the viewers. Additionally, or alternatively, the PDLC material may periodically operate in the opaque state to reduce light from a first image displayed in one direction from filtering into a second image displayed in the other direction. Accordingly, the PDLC material may improve the quality of the images displayed in one or both of the directions.

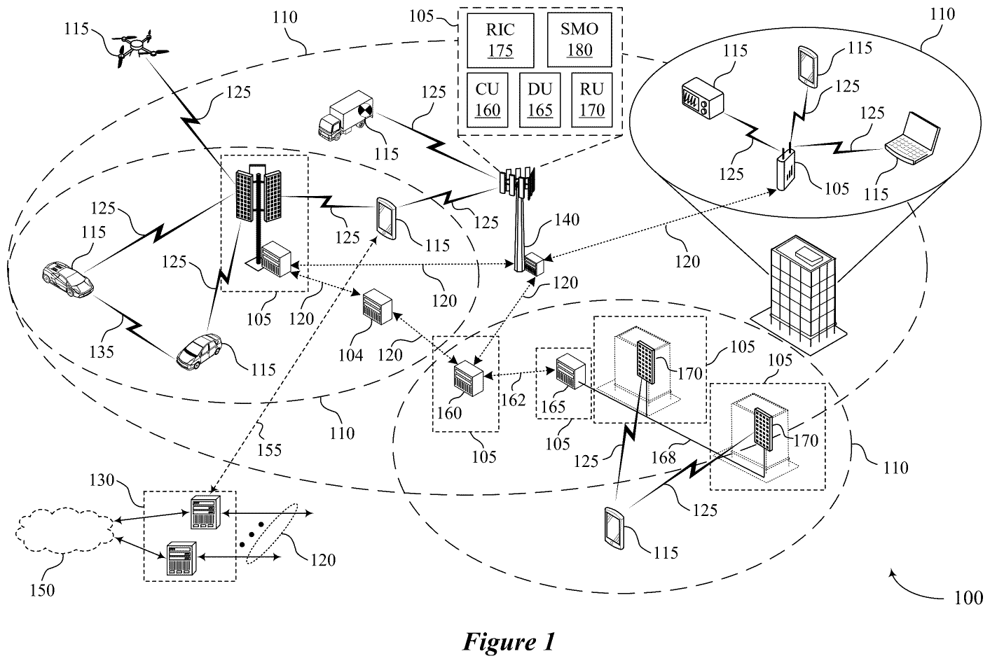

FIG. 1 shows an example of a wireless communications system 100 that supports transparent displays with two-way viewing angles. The wireless communications system 100 may include one or more network entities 105, one or more UEs 115, and a core network 130. In some implementations, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some implementations, network entities 105 and UEs 115 may wirelessly communicate via one or more communication links 125 (such as a radio frequency (RF) access link). For example, a network entity 105 may support a coverage area 110 (such as a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (such as any network entity described herein), a UE 115 (such as any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some implementations, network entities 105 may communicate with the core network 130, or with one another, or both. For example, network entities 105 may communicate with the core network 130 via one or more backhaul communication links 120 (such as in accordance with an S1, N2, N3, or other interface protocol). In some implementations, network entities 105 may communicate with one another via a backhaul communication link 120 (such as in accordance with an X2, Xn, or other interface protocol) either directly (such as directly between network entities 105) or indirectly (such as via a core network 130). In some implementations, network entities 105 may communicate with one another via a midhaul communication link 162 (such as in accordance with a midhaul interface protocol) or a fronthaul communication link 168 (such as in accordance with a fronthaul interface protocol), or any combination thereof. The backhaul communication links 120, midhaul communication links 162, or fronthaul communication links 168 may be or include one or more wired links (such as an electrical link, an optical fiber link), one or more wireless links (such as a radio link, a wireless optical link), among other examples or various combinations thereof. A UE 115 may communicate with the core network 130 via a communication link 155.

One or more of the network entities 105 described herein may include or may be referred to as a base station (BS) 140 (such as a base transceiver station, a radio BS, an NR BS, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some implementations, a network entity 105 (such as a BS 140) may be implemented in an aggregated (such as monolithic, standalone) BS architecture, which may be configured to utilize a protocol stack that is physically or logically integrated within a single network entity 105 (such as a single RAN node, such as a BS 140).

In some implementations, a network entity 105 may be implemented in a disaggregated architecture (such as a disaggregated BS architecture, a disaggregated RAN architecture), which may be configured to utilize a protocol stack that is physically or logically distributed among two or more network entities 105, such as an integrated access backhaul (IAB) network, an open RAN (O-RAN) (such as a network configuration sponsored by the O-RAN Alliance), or a virtualized RAN (vRAN) (such as a cloud RAN (C-RAN)). For example, a network entity 105 may include one or more of a central unit (CU) 160, a distributed unit (DU) 165, a radio unit (RU) 170, a RAN Intelligent Controller (RIC) 175 (such as a Near-Real Time RIC (Near-RT RIC), a Non-Real Time RIC (Non-RT RIC)), a Service Management and Orchestration (SMO) 180 system, or any combination thereof. An RU 170 also may be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (such as separate physical locations). In some implementations, one or more network entities 105 of a disaggregated RAN architecture may be implemented as virtual units (such as a virtual CU (VCU), a virtual DU (VDU), a virtual RU (VRU)).

The split of functionality between a CU 160, a DU 165, and an RU 170 is flexible and may support different functionalities depending on which functions (such as network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some implementations, the CU 160 may host upper protocol layer (such as layer 3 (L3), layer 2 (L2)) functionality and signaling (such as Radio Resource Control (RRC), service data adaptation protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (such as physical (PHY) layer) or L2 (such as radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (such as via one or more RUs 170). In some implementations, a functional split between a CU 160 and a DU 165, or between a DU 165 and an RU 170 may be within a protocol layer (such as some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (such as F1, F1-c, F1-u), and a DU 165 may be connected to one or more RUs 170 via a fronthaul communication link 168 (such as open fronthaul (FH) interface). In some implementations, a midhaul communication link 162 or a fronthaul communication link 168 may be implemented in accordance with an interface (such as a channel) between layers of a protocol stack supported by respective network entities 105 that are in communication via such communication links.

In wireless communications systems (such as wireless communications system 100), infrastructure and spectral resources for radio access may support wireless backhaul link capabilities to supplement wired backhaul connections, providing an IAB network architecture (such as to a core network 130). In some implementations, in an IAB network, one or more network entities 105 (such as IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (such as a donor BS 140). The one or more donor network entities 105 (such as IAB donors) may be in communication with one or more additional network entities 105 (such as IAB nodes 104) via supported access and backhaul links (such as backhaul communication links 120). IAB nodes 104 may include an IAB mobile termination (IAB-MT) controlled (such as scheduled) by DUs 165 of a coupled IAB donor. An IAB-MT may include an independent set of antennas for relay of communications with UEs 115, or may share the same antennas (such as of an RU 170) of an IAB node 104 used for access via the DU 165 of the IAB node 104 (such as referred to as virtual IAB-MT (vIAB-MT)). In some implementations, the IAB nodes 104 may include DUs 165 that support communication links with additional entities (such as IAB nodes 104, UEs 115) within the relay chain or configuration of the access network (such as downstream). In such implementations, one or more components of the disaggregated RAN architecture (such as one or more IAB nodes 104 or components of IAB nodes 104) may be configured to operate according to the techniques described herein.

In the implementation of the techniques described herein applied in the context of a disaggregated RAN architecture, one or more components of the disaggregated RAN architecture may be configured to support transparent display supporting a two-way viewing angle as described herein. For example, some operations described as being performed by a UE 115 or a network entity 105 (such as a BS 140) may additionally, or alternatively, be performed by one or more components of the disaggregated RAN architecture (such as IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” also may be referred to as a unit, a station, a terminal, or a client, among other examples. A UE 115 also may include or may be referred to as a personal electronic device such as a cellular phone, a personal digital assistant (PDA), a tablet computer, a laptop computer, or a personal computer. In some implementations, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay BSs, among other examples, as shown in FIG. 1.

The UEs 115 and the network entities 105 may wirelessly communicate with one another via one or more communication links 125 (such as an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (such as a bandwidth part (BWP)) that is operated according to one or more physical layer channels for a given radio access technology (such as LTE, LTE-A, LTE-A Pro, NR). Each physical layer channel may carry acquisition signaling (such as synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (such as entity, sub-entity) of a network entity 105. For example, the terms “transmitting,” “receiving,” or “communicating,” when referring to a network entity 105, may refer to any portion of a network entity 105 (such as a BS 140, a CU 160, a DU 165, a RU 170) of a RAN communicating with another device (such as directly or via one or more other network entities 105).

Signal waveforms transmitted via a carrier may be made up of multiple subcarriers (such as using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (such as a duration of one modulation symbol) and one subcarrier, for which the symbol period and subcarrier spacing may be inversely related. The quantity of bits carried by each resource element may depend on the modulation scheme (such as the order of the modulation scheme, the coding rate of the modulation scheme, or both), such that a relatively higher quantity of resource elements (such as in a transmission duration) and a relatively higher order of a modulation scheme may correspond to a relatively higher rate of communication. A wireless communications resource may refer to a combination of an RF spectrum resource, a time resource, and a spatial resource (such as a spatial layer, a beam), and the use of multiple spatial resources may increase the data rate or data integrity for communications with a UE 115.

The time intervals for the network entities 105 or the UEs 115 may be expressed in multiples of a basic time unit which may, in some implementations, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (such as 10 milliseconds (ms)). Each radio frame may be identified by a system frame number (SFN) (such as ranging from 0 to 1023).

Each frame may include multiple consecutively numbered subframes or slots, and each subframe or slot may have the same duration. In some implementations, a frame may be divided (such as in the time domain) into subframes, and each subframe may be further divided into a quantity of slots. Alternatively, each frame may include a variable quantity of slots, and the quantity of slots may depend on subcarrier spacing. Each slot may include a quantity of symbol periods (such as depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (such as N_{f}) sampling periods. The duration of a symbol period may depend on the subcarrier spacing or frequency band of operation.

A subframe, a slot, a mini-slot, or a symbol may be the smallest scheduling unit (such as in the time domain) of the wireless communications system 100 and may be referred to as a transmission time interval (TTI). In some implementations, the TTI duration (such as a quantity of symbol periods in a TTI) may be variable. Additionally, or alternatively, the smallest scheduling unit of the wireless communications system 100 may be dynamically selected (such as in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (such as a control resource set (CORESET)) for a physical control channel may be defined by a set of symbol periods and may extend across the system bandwidth or a subset of the system bandwidth of the carrier. One or more control regions (such as CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (such as control channel elements (CCEs)) associated with encoded information for a control information format having a given payload size. Search space sets may include common search space sets configured for sending control information to multiple UEs 115 and UE-specific search space sets for sending control information to a specific UE 115.

In some implementations, a network entity 105 (such as a BS 140, an RU 170) may be movable and therefore provide communication coverage for a moving coverage area 110. In some implementations, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some implementations, a UE 115 may be configured to support communicating directly with other UEs 115 via a device-to-device (D2D) communication link 135 (such as in accordance with a peer-to-peer (P2P), D2D, or sidelink protocol). In some implementations, one or more UEs 115 of a group that are performing D2D communications may be within the coverage area 110 of a network entity 105 (such as a BS 140, an RU 170), which may support aspects of such D2D communications being configured by (such as scheduled by) the network entity 105. In some implementations, one or more UEs 115 of such a group may be outside the coverage area 110 of a network entity 105 or may be otherwise unable to or not configured to receive transmissions from a network entity 105. In some implementations, groups of the UEs 115 communicating via D2D communications may support a one-to-many (1:M) system in which each UE 115 transmits to each of the other UEs 115 in the group. In some implementations, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (such as UEs 115). In some implementations, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some implementations, vehicles in a V2X system may communicate with roadside infrastructure, such as roadside units, or with the network via one or more network nodes (such as network entities 105, BSs 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (such as a mobility management entity (MME), an access and mobility management function (AMF)) and at least one user plane entity that routes packets or interconnects to external networks (such as a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (such as BSs 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communication using UHF waves may be associated with smaller antennas and shorter ranges (such as less than 100 kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some implementations, operations using unlicensed bands may depend on a carrier aggregation configuration in conjunction with component carriers operating using a licensed band (such as LAA). Operations using unlicensed spectrum may include downlink transmissions, uplink transmissions, P2P transmissions, or D2D transmissions, among other examples.

A network entity 105 (such as a BS 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more BS antennas or antenna arrays may be co-located at an antenna assembly, such as an antenna tower. In some implementations, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which also may be referred to as spatial filtering, directional transmission, or directional reception, is a signal processing technique that may be used at a transmitting device or a receiving device (such as a network entity 105, a UE 115) to shape or steer an antenna beam (such as a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (such as with respect to the antenna array of the transmitting device or receiving device, or with respect to some other orientation).

In some wireless communications systems 100, a device may include a transparent display. A transparent display may include a screen that allows a viewer to see through the screen, while also displaying an image on the screen. Some examples of devices that may use transparent displays include augmented reality (AR) or extended reality (XR) glasses, wearable devices, tablet devices, cameras and camera view displays, gaming consoles, cockpit controls, electronic billboards or signs, architectural structures, appliances, smart windows, smart desk dividers, smart televisions, windshields or other windows of vehicles, or any combination thereof. Some transparent displays may support unidirectional viewing. For example, a transparent display may include a unidirectional-emitting OLED, such as a top-emitting OLED or a bottom-emitting OLED. Such displays may allow users to view contents in one direction (such as via one side of a transparent or semi-transparent screen), but may preclude users from viewing contents in another direction (such as via the other side of the transparent or semi-transparent screen). Alternatively, some transparent displays may include a bidirectional-emitting OLED that may emit light in two directions. However, such displays may allow users to correctly view contents in one direction (such as via one side of the transparent or semi-transparent screen), but may cause users to view a mirror image of the contents in the other direction (such as via the other side of the transparent or semi-transparent screen). Additionally, or alternatively, sensitive information displayed by one side of the screen may be viewable (as a mirror image) on the other side of the screen, potentially leading to security concerns.

A device, such as a UE 115 or a network entity 105, may use techniques described herein to support a two-way viewing angle for transparent displays. For example, the device may include a transparent or semi-transparent screen (such as a screen with a greater than 50% transparency) that includes a set of pixels for displaying images. The screen may include a first substrate and a second substrate, such as two glass panes on either side of the screen. A pixel of the screen may be configured with an OLED or another display technology between the two substrates. For example, the pixel may include an OLED formed on the first substrate and oriented to display in a first direction towards the second substrate. The pixel may further include a set of switchable mirrors and a PDLC material. A switchable mirror may be an example of a liquid crystal material that may reflect light or allow light to pass through the material according to an electric current applied to the switchable mirror. The switchable mirror may reflect the light while operating in a “mirrored” state and may allow the light to pass through while operating in a “transparent” state. The PDLC material may scatter light or allow light to pass through the material according to an electric current applied to the PDLC material. The PDLC material may scatter the light while operating in an “opaque” state and may allow the light to pass through while operating in a “transparent” state. By switching the states of the switchable mirrors and the PDLC material, the pixel may display contents either in the first direction via the second substrate (through one side of the screen) or in a second direction via the first substrate (through the other side of the screen). The screen may display different contents in the different directions or may display the same contents with different orientations in the different directions, such that viewers in either direction can view the contents in a readable format. For example, neither side may view a reflection of the contents displayed for the other side.

Such transparent displays with two-way viewing angles may allow for different viewing experiences on different sides of the displays or improved, consistent viewing experiences on different sides of the displays. For example, a smart vehicle may display information important to the driver or passengers via one side (the inside) of a windshield, but may display different information to pedestrians or other vehicles via the other side (the outside) of the windshield. In some implementations, the different sides of the display may display information using different languages to improve communications between users with different native languages. Additionally, or alternatively, in a sporting arena, a transparent scoreboard can accurately show the score or other information in the proper orientation to fans on either side of the arena, instead of one side of the arena seeing a mirrored image of the information. Shops may use such transparent displays in store windows to display different information to pedestrians outside the shops than to customers inside the shops. A transparent desk divider may display different information (such as organizational news, announcements, calendars) in a readable format to the workers working on either side of the desk divider, while still allowing the workers to see each other through the transparent divider.

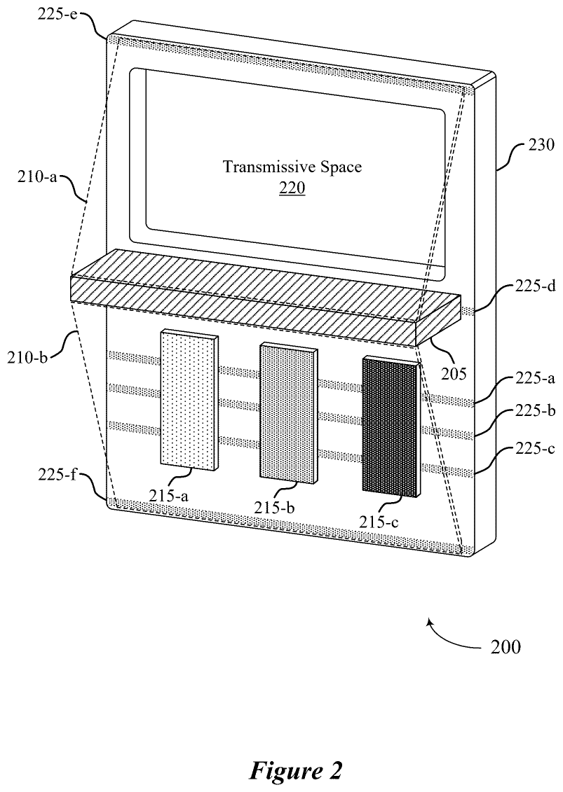

FIG. 2 shows an example of a pixel configuration 200 that supports a transparent display with a two-way viewing angle. A transparent display may include multiple pixels configured according to the pixel configuration 200, where each pixel may display a specific color at a specific time (such as corresponding to a specific timestamp). Together, the multiple pixels may display an image via the transparent display. In some implementations, a UE or a network entity, such as a UE 115 or a network entity 105 as described with reference to FIG. 1, may include a transparent display using the pixel configuration 200. In some other implementations, other devices may include a transparent display using the pixel configuration 200.

The pixel configuration 200 may include a transmissive space 220 allowing for a viewer to see through the pixel. For example, the transmissive space 220 may include a clear film or other transparent or translucent material. The pixel configuration 200 may be transparent or partially transparent (such as capable of 70 to 85% transparency) according to the transmissive space 220. The pixel configuration 200 also may include one or more substrates, such as a substrate 230. The substrate 230 may be transparent or translucent to allow for a viewer to see through the transmissive space 220. For example, the substrate 230 may be an example of a glass substrate, such as a glass pane, or a plastic substrate. The transparent display may include an additional substrate, such that the components of the pixel configuration 200 are located between the substrate 230 and another substrate. For example, the components may be positioned between two panes of glass. In some implementations, the substrate 230 may be parallel to the other substrate.

The pixel configuration 200 may include an OLED pixel. The OLED pixel may include one or more OLED materials (such as organic layers) applied to, or otherwise formed on, the substrate 230. For example, the OLED materials may be condensed on the substrate 230, deposited on to the substrate 230, sprayed onto the substrate 230, or otherwise applied to the substrate 230. The OLED materials may be examples of, or otherwise include one or more emissive electroluminescent layers (such as organic compounds) that emit light in response to electric currents.

The OLED pixel may include one or more sub-pixels supporting emissions of different colors. In some implementations, the OLED pixel may include a first sub-pixel 215-a configured to emit a first color light, a second sub-pixel 215-b configured to emit a second color light, and a third sub-pixel 215-c configured to emit a third color light. For example, the first sub-pixel 215-a may emit red light, the second sub-pixel 215-b may emit green light, and the third sub-pixel 215-c may emit blue light to support a red-green-blue (RGB) color scheme for display. Alternatively, the OLED pixel may use any quantity of sub-pixels or any color scheme for display. In some implementations, the sub-pixels may be different OLED materials that emit different wavelengths of light, which may correspond to different colors. In some other implementations, the OLED pixel may include an OLED material configured to emit white light, and the OLED pixel may include one or more filters (such as a red filter, a green filter, and a blue filter) to filter the light with the different colors.

The pixel configuration 200 may additionally include one or more metal lines (such as conductive lines) with relatively high transmissivity configured to apply one or more voltages to the OLED pixel to trigger an emission of light. In some implementations, the pixel configuration 200 may include one metal line 225-a, and the OLED pixel may display a color (such as output a first emission corresponding to a first color) in accordance with a voltage applied to the OLED pixel by the metal line 225-a. In some other implementations, the pixel configuration 200 may include a first metal line 225-a corresponding to the first sub-pixel 215-a, a second metal line 225-b corresponding to the second sub-pixel 215-b, and a third metal line 225-c corresponding to the third sub-pixel 215-c. The OLED pixel may display a color (such as output a first emission of the color) including a first color in accordance with a first voltage applied to the first sub-pixel 215-a by the first metal line 225-a, a second color in accordance with a second voltage applied to the second sub-pixel 215-b by the second metal line 225-b, a third color in accordance with a third voltage applied to the third sub-pixel 215-c by the third metal line 225-c, or some combination thereof. The OLED pixel may display the color in a first direction. For example, the OLED pixel may be an example of a top-emitting OLED configured to display the color away from the substrate 230.

To support two-way viewing of images from the transparent display, the pixel configuration 200 may further include a PDLC material 205 and a set of switchable mirrors, including a first switchable mirror 210-a and a second switchable mirror 210-b. The pixel configuration 200 may use the PDLC material 205 and the switchable mirrors together in a three-dimensional prism structure to support displaying different images in different directions using emissions from the OLED pixel in a single direction. The PDLC material 205 may be an example of PDLC glass, PDLC plastic, or a PDLC film applied to some other material. The PDLC material 205 may be an example of a light-modulating material that scatters light different in accordance with an electric field applied to the material. For example, the PDLC material 205 may include liquid crystals arranged in a scattered droplet pattern. Such an arrangement of liquid crystals may scatter light passing through the PDLC material 205, causing the PDLC material 205 to be opaque or otherwise non-transparent. However, applying a voltage to the PDLC material 205 may cause the liquid crystals to react and align. The aligned liquid crystals may allow light through the PDLC material 205, causing the PDLC material 205 to be transparent (such as partially transparent). In some implementations, approximately 90% of light may be blocked by the PDLC material 205 in the opaque state, and approximately 75% of light may pass through the PDLC material 205 in the transparent state. However, other PDLC materials may support other percentages of opacity and transparency, for example, in accordance with material properties of the PDLC materials. The pixel configuration 200 may include a metal line 225-d (such as a conductive line) coupled with the PDLC material 205 and configured to apply one or more voltages to the PDLC material 205 to cause the PDLC material 205 to switch states (such as between the opaque state and the transparent state).

A switchable mirror may be similar to the PDLC material 205. However, instead of an opaque state, the switchable mirror may support a mirrored state. For example, the switchable mirror may include a special type of PDLC material (or another liquid crystal material), where the liquid crystal arrangement may reflect light (rather than scattering the light). Similar to the PDLC material 205, applying a voltage to the switchable mirror may cause the liquid crystals to react and align. The aligned liquid crystals may allow light through the switchable mirror, causing the switchable mirror to be transparent or partially transparent. The pixel configuration 200 may include one or more metal lines (such as conductive lines) coupled with the set of switchable mirrors and configured to apply one or more voltages to the switchable mirrors to cause the switchable mirrors to switch states (such as between the mirrored state and the transparent state). In some implementations, the pixel configuration 200 may include a shared metal line 225-e that applies a voltage to the set of switchable mirrors (such as both the first switchable mirror 210-a and the second switchable mirror 210-b). The shared metal line 225-e may apply a same voltage (or approximately the same voltage) to the first switchable mirror 210-a and the second switchable mirror 210-b at a same time (or approximately the same time), causing the set of switchable mirrors to change states concurrently. In some other implementations, the pixel configuration 200 may include a first metal line 225-e that applies a first voltage to the first switchable mirror 210-a and a second metal line 225-f that applies a second voltage to the second switchable mirror 210-b. A controller may cause the first metal line 225-e and the second metal line 225-f to switch the states of the set of switchable mirrors in tandem.

The pixel configuration 200 may use the PDLC material 205 and the set of switchable mirrors to display different emissions from the OLED pixel in different directions. For example, the OLED pixel may emit light (such as a first emission with a first color) in a first direction away from the substrate 230 and towards the second switchable mirror 210-b. If the second switchable mirror 210-b is in the transparent state, the first emission may be visible through the second switchable mirror 210-b. Concurrently, the PDLC material 205 may be in the opaque state, such that the first emission (or a significant portion of the first emission) does not permeate into the transmissive space 220. The first switchable mirror 210-a also may be in the transparent state to allow a viewer to see through the pixel via the transmissive space 220. Accordingly, the pixel configuration 200 may display the first color in the first direction in accordance with the set of switchable mirrors being in the transparent state and the PDLC material 205 being in the opaque state.

Alternatively, if the second switchable mirror 210-b is in the mirrored state, the first emission (or a significant portion of the first emission) may not be visible through the second switchable mirror 210-b in the first direction. Instead, the first emission may reflect off the second switchable mirror 210-b towards the PDLC material 205 and the first switchable mirror 210-a. If the PDLC material 205 is in the transparent state and the first switchable mirror 210-a is in the mirrored state, the first emission may pass through the PDLC material 205 and may reflect off the first switchable mirror 210-a and through the transmissive space 220. Accordingly, the first emission transmitted in the first direction may be reflected through the transmissive space 220 in a second direction (such as opposite the first direction or otherwise different from the first direction). In some implementations, the first switchable mirror 210-a and the second switchable mirror 210-b may be oriented at specific angles to support reflection of the first emission. For example, the first switchable mirror 210-a, the second switchable mirror 210-b, or both may be oriented at a first angle to the OLED (such as a 45 degree angle), oriented at a second angle to the substrate 230 (such as a 45 degree angle), or both. The first switchable mirror 210-a and the second switchable mirror 210-b may converge at a third angle (such as a 90 degree angle). The PDLC material 205 may split the third angle between the first switchable mirror 210-a and the second switchable mirror 210-b. In some implementations, the PDLC material 205 may bisect the third angle between the first switchable mirror 210-a and the second switchable mirror 210-b. In some other implementations, the PDLC material 205 may divide the third angle unevenly, supporting other configurations for reflecting emissions (such as in different directions or for different displayable surface sizes). The pixel configuration 200 may display the first color in the second direction in accordance with the set of switchable mirrors being in the mirrored state and the PDLC material 205 being in the transparent state.

The pixel configuration 200 may display content (such as different colors, creating different images across a set of multiple pixels) in the different directions according to a display frequency (such as 30 Hertz (Hz), 60 Hz). For example, the content may be displayed at a frequency synchronized with the changing of states of the prism materials (such as the PDLC material 205 and the set of switchable mirrors). For example, a set of pixels in a transparent display configured according to the pixel configuration 200 may display a first image in the first direction at a first time. The pixel configuration 200 may switch the states of the PDLC material 205 and the set of switchable mirrors to display a second image in the second direction at a second time. The pixel configuration 200 may switch back the states of the PDLC material 205 and the set of switchable mirrors to display the first image (or a next image after the first image in a series of images) in the first direction at a third time. By switching the images and states of the materials according to the display frequency, the transparent display may display two different views (such as two different images, two different series of images) for two different sides of the transparent display, such as via two screens or two sides of a screen. For example, if the display frequency is 30 Hz, the pixel configuration 200 may display first content in the first direction 15 times in a second and may display second content in the second direction 15 times in the second (at alternating times). When the first content is displayed in the first direction, the pixel configuration 200 may refrain from displaying content in the second direction, and when the second content is displayed in the second direction, the pixel configuration 200 may refrain from displaying content in the first direction. At frequencies that satisfy a threshold frequency (such as display frequencies that meet or exceed a threshold frequency of 30 Hz), the content on each side may appear to be constantly displayed to the human eye. A viewer in the first direction may see the first content without seeing the second content, and a viewer in the second direction may see the second content without seeing the first content. Accordingly, the pixel configuration 200 may support a transparent display that provides correct directional content on two sides. The PDLC material 205 may protect against content displayed for one side bleeding into the image displayed for the other side.

Alternative configurations or materials may be used to achieve similar two-way displays for a transparent display. For example, the pixel configuration 200 may support any angles between the switchable mirrors, the PDLC material 205, the OLED pixel, the substrate 230, or any combination thereof. In some implementations, different angles may result in different display directions, such that the pixel configuration 200 may support displays in two directions that are not 180 degrees apart. Additionally, or alternatively, the pixel configuration 200 may include additional switchable mirrors, PDLC materials or both to support displaying images in more than two directions via a transparent display.

Additionally, or alternatively, the PDLC material 205 and switchable mirror materials may react differently to different applied voltages. In some implementations, the PDLC material 205 may be in a transparent state in accordance with a conductive line (such as the metal line 225-d) applying a first voltage to the PDLC material 205. In some other implementations, the PDLC material 205 may be in the transparent state in accordance with no voltage being applied to the PDLC material 205. Additionally, or alternatively, in some implementations, the PDLC material 205 may be in an opaque state in accordance with the conductive line (such as the metal line 225-d) applying a second voltage to the PDLC material 205. In some other implementations, the PDLC material 205 may be in the opaque state in accordance with no voltage being applied to the PDLC material 205. Similarly, in some implementations, the switchable mirrors may be in a transparent state in accordance with one or more conductive lines (such as the metal line 225-e, the metal line 225-f) applying a first voltage to the switchable mirrors. In some other implementations, the switchable mirrors may be in the transparent state in accordance with no voltage being applied to the switchable mirrors. Additionally, or alternatively, in some implementations, the switchable mirrors may be in a mirrored state in accordance with one or more conductive lines (such as the metal line 225-e, the metal line 225-f) applying a second voltage to the switchable mirrors. In some other implementations, the switchable mirrors may be in the mirrored state in accordance with no voltage being applied to the switchable mirrors.

In some implementations, a conductive line may provide electrical current to multiple components of the pixel configuration 200. For example, a shared conductive line may be coupled with both the first switchable mirror 210-a and the second switchable mirror 210-b to apply a voltage to both the first switchable mirror 210-a and the second switchable mirror 210-b. Additionally, or alternatively, a shared conductive line may be coupled with the PDLC material 205, the first switchable mirror 210-a, and the second switchable mirror 210-b to concurrently apply a voltage to the PDLC material 205, the first switchable mirror 210-a, and the second switchable mirror 210-b.

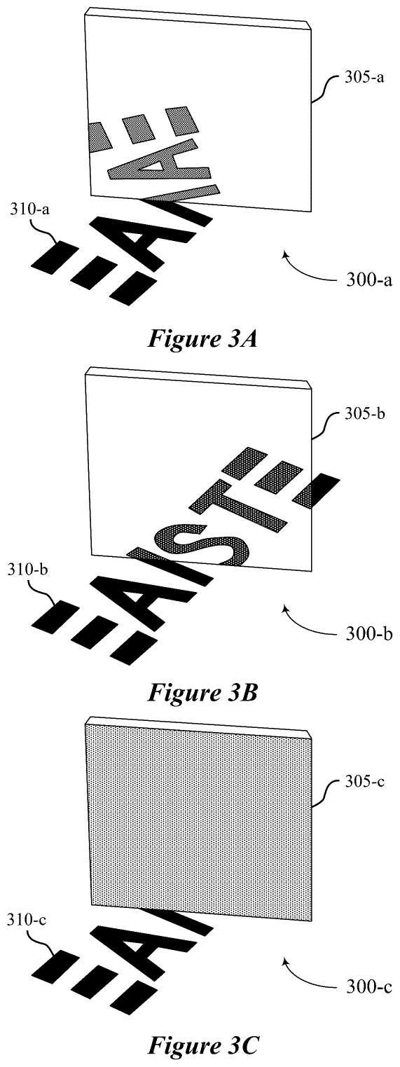

FIGS. 3A, 3B and 3C show examples of different operational states for materials that support transparent displays with two-way viewing angles.

FIG. 3A shows an example of an operational state 300-a for a material 305-a that supports a transparent display with a two-way viewing angle. The material 305-a may be an example of a switchable mirror, such as a switchable mirror 210-a or a switchable mirror 210-b as described with reference to FIG. 2. The material 305-a may switch between operational states in accordance with a voltage applied to the material 305-a. In some implementations, the material 305-a may support a spectrum of operational states between a mirrored state and a transparent state. The voltage applied to the material 305-a may cause the material 305-a to change a reflectivity of the material 305-a and a transparency of the material 305-a. Accordingly, the material 305-a may support reflecting light from the material 305-a, allowing light to pass through the material 305-a, or some combination thereof.

The operational state 300-a may be an example of a mirrored state. For example, the material 305-a may reflect an image 310-a in accordance with a voltage applied to the material 305-a. In some implementations, a system (such as a processing system) may refrain from applying a voltage to the material 305-a to cause the material 305-a to operate in the mirrored state. In some other implementations, the system may apply a first voltage or a first range of voltages to cause the material 305-a to operate in the mirrored state.

FIG. 3B shows an example of an operational state 300-b for a material 305-b that supports a transparent display with a two-way viewing angle. The operational state 300-b may be an example of a transparent state for the material 305-b. In some implementations, the material 305-b may be an example of a switchable mirror, such as a switchable mirror 210-a, a switchable mirror 210-b, or a material 305-a as described with reference to FIGS. 2 and 3A. For example, a system (such as a processing system) may apply a second voltage or a second range of voltages to the material 305-b to cause the material 305-b (such as a switchable mirror) to operate in the transparent state. In the transparent state, the material 305-b may allow an image 310-b to be displayed through the material 305-b.

In some other implementations, the material 305-b may be an example of a PDLC material, such as a PDLC material 205 as described with reference to FIG. 2. In some such implementations, the material 305-b may support a spectrum of operational states between a transparent state and an opaque state. The voltage applied to the material 305-b may cause the material 305-b to change an opacity of the material 305-b and a transparency of the material 305-b. Accordingly, the material 305-b may support blocking light from passing through the material 305-b, allowing light to pass through the material 305-b, or some combination thereof. For example, the material 305-b may allow the image 310-b to be displayed through the material 305-b in accordance with allowing light to pass through the material 305-b. For example, the system (such as the processing system) may apply a third voltage or a third range of voltages to the material 305-b to cause the material 305-b (such as a PDLC material) to operate in the transparent state.

FIG. 3C shows an example of an operational state 300-c for a material 305-c that supports a transparent display with a two-way viewing angle. The operational state 300-c may be an example of an opaque state for the material 305-c. The material 305-c may be an example of a PDLC material, such as a PDLC material 205 or a material 305-b as described with reference to FIGS. 2 and 3B. In some implementations, a system (such as a processing system) may refrain from applying a voltage to the material 305-c to cause the material 305-c to operate in the opaque state. In some other implementations, the system may apply a fourth voltage or a fourth range of voltages to the material 305-c to cause the material 305-c to operate in the opaque state. In the opaque state, the material 305-c may preclude (or otherwise block) an image 310-c from being displayed through the material 305-c.

An OLED pixel may include any of the materials described herein with reference to FIGS. 3A, 3B and 3C as components of the OLED pixel. Such components may switch between operational states to support displaying images in different directions.

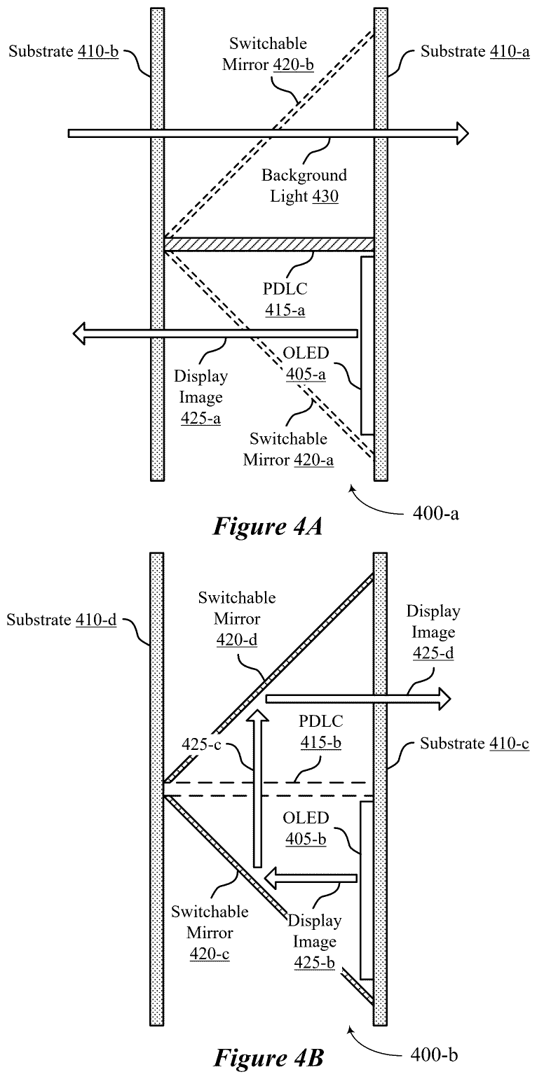

FIGS. 4A and 4B show examples of display configurations for directional displays.

FIG. 4A shows an example of a display configuration 400-a for a directional display in a first direction. The display configuration 400-a may include an OLED 405-a (which may be an example of an OLED pixel as described with reference to FIG. 2), a first substrate 410-a (which may be an example of a substrate 230 as described with reference to FIG. 2), a second substrate 410-b (such as parallel to the first substrate 410-a), a PDLC material 415-a (which may be an example of a PDLC material 205 as described with reference to FIG. 2), and a set of switchable mirrors including a first switchable mirror 420-a and a second switchable mirror 420-b (which may be an example of a second switchable mirror 210-b and a first switchable mirror 210-a as described with reference to FIG. 2). A UE or network entity, such as a UE 115 or a network entity 105 as described with reference to FIG. 1, or any other device with a transparent or semi-transparent screen may support the display configuration 400-a. The display configuration 400-a may display content (such as an image, a color, or any other emission) in the first direction in accordance with current states of the PDLC material 415-a and the set of switchable mirrors.

The OLED 405-a may emit light of a first color in the first direction as a first emission 425-a. The first emission 425-a may correspond to first content for display in the first direction. To display the first content in the first direction, the switchable mirrors (such as the first switchable mirror 420-a, the first switchable mirror 420-a and the second switchable mirror 420-b) may be set to a transparent mode and the PDLC material 415-a may be set to an opaque mode. The first content (such as the first emission 425-a) may pass through the first switchable mirror 420-a in the transparent mode and through the second substrate 410-b to display in the first direction. In some implementations, a controller, such as a processing system, may apply a threshold voltage to one or more terminals of the first switchable mirror 420-a to cause the first switchable mirror 420-a to operate in the transparent state. The second switchable mirror 420-b may operate in the transparent mode to allow viewers to see through the transparent display (such as allowing light 430 to pass through the transparent display) to the other side. The PDLC material 415-a may operate in the opaque state to block the first emission 425-a from filtering into the light 430. Accordingly, the PDLC material 415-a may improve the quality of images displayed in one or both directions. In some implementations, the controller may apply a threshold voltage to one or more terminals of the PDLC material 415-a to cause the PDLC material 415-a to operate in the opaque state.

FIG. 4B shows an example of a display configuration 400-b for a directional display in a second direction. The display configuration 400-b may include an OLED 405-b (which may be an example of an OLED pixel as described with reference to FIG. 2), a first substrate 410-c (which may be an example of a substrate 230 as described with reference to FIG. 2), a second substrate 410-d (such as parallel to the first substrate 410-c), a PDLC material 415-b (which may be an example of a PDLC material 205 as described with reference to FIG. 2), and a set of switchable mirrors including a first switchable mirror 420-c and a second switchable mirror 420-d (which may be an example of a second switchable mirror 210-b and a first switchable mirror 210-a as described with reference to FIG. 2). A UE or network entity, such as a UE 115 or a network entity 105 as described with reference to FIG. 1, or any other device with a transparent or semi-transparent screen may support the display configuration 400-b. The display configuration 400-b may display content (such as an image, a color, or any other emission) in the second direction in accordance with current states of the PDLC material 415-b and the set of switchable mirrors. For example, the OLED 405-b may display an image in one direction, which may be reflected through a three-dimensional prism configuration of the PDLC material 415-b and the set of switchable mirrors to be displayed in a different direction.

The OLED 405-b may emit light of a second color in the first direction as a second emission 425-b. The second emission 425-b may correspond to second content for display in the second direction different from the first direction. To display the second content in the second direction, the switchable mirrors (such as the first switchable mirror 420-c and the second switchable mirror 420-d) may be set to a mirrored mode and the PDLC material 415-b may be set to a transparent mode. The second content (such as the second emission 425-b) may reflect off the first switchable mirror 420-c as reflected emission 425-c, pass through the PDLC material 415-b, and reflect off the second switchable mirror 420-d as reflected emission 425-d. The reflected emission 425-d may pass through the first substrate 410-c to display in the second direction (such as opposite, or otherwise different from, the first direction). In some implementations, a controller, such as a processing system, may apply a threshold voltage to one or more terminals of the first switchable mirror 420-c and the second switchable mirror 420-d to cause the first switchable mirror 420-c and the second switchable mirror 420-d to operate in the mirrored state. In some implementations, the controller may apply a threshold voltage to one or more terminals of the PDLC material 415-b to cause the PDLC material 415-b to operate in the transparent state.

If the transparent or semi-transparent screen is off (such as when the OLED 405-b is powered down and not emitting light), the PDLC material 415-b, the first switchable mirror 420-c, and the second switchable mirror 420-d may be set to the transparent mode. Accordingly, the PDLC material 415-b, the first switchable mirror 420-c, and the second switchable mirror 420-d may allow viewers to see through the screen if the screen display is off.

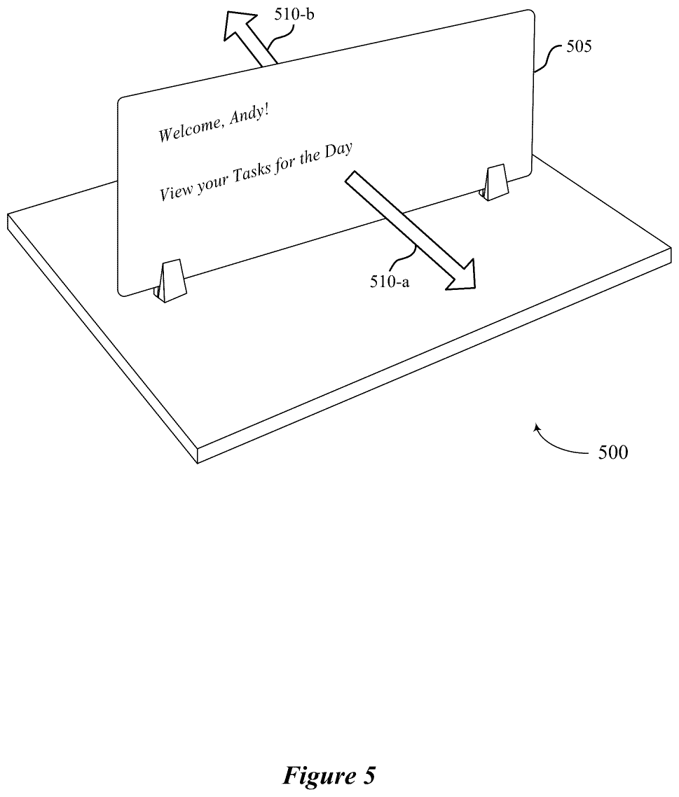

FIG. 5 shows an example use case 500 for a transparent display with a two-way viewing angle. The example use case 500 may include a transparent desk divider 505 that supports displaying different images in different directions. For example, the transparent desk divider 505 may include pixels configured according to the pixel configuration 200 as described with reference to FIG. 2. Users may work on either side of the transparent desk divider 505 and may view different information (such as different images) displayed via the different sides of the transparent desk divider 505. For example, a first user may view first information displayed by the transparent desk divider 505 in a first direction 510-a. This first information may be personalized for the first user, such as a message stating, “Welcome, Andy!” and an instruction stating, “View your Tasks for the Day.” In some implementations, the first user may interact with the transparent desk divider 505 to update the first information displayed in the first direction 510-a. In contrast, a second user working on the other side of the transparent desk divider 505 may view second information displayed by the transparent desk divider 505 in a second direction 510-b. The second information may be personalized for the second user. Accordingly, the first and second users may view different information displayed in the different directions. Additionally, the transparent desk divider 505 may use the display configurations described with reference to FIGS. 4A and 4B to display the information in the different directions. Accordingly, the pixel configuration of the pixels of the transparent desk divider 505 may preclude the first user from viewing the second information through the transparent desk divider 505 and may preclude the second user from viewing the first information through the transparent desk divider 505.

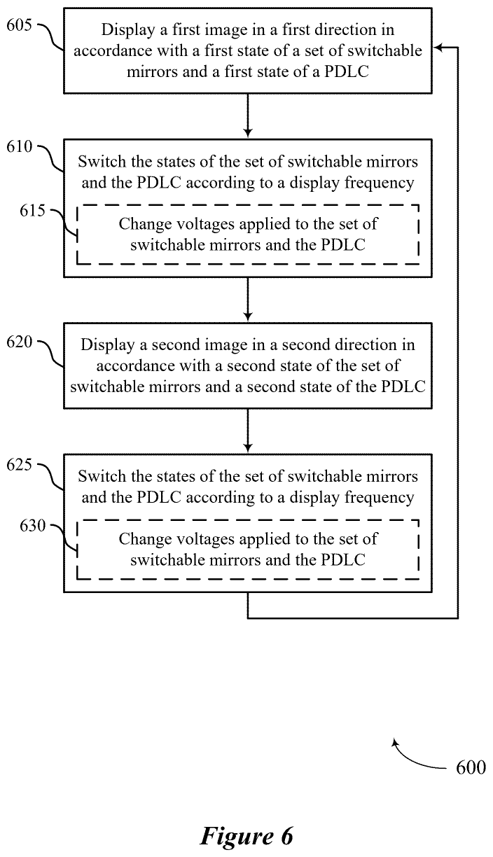

FIG. 6 shows an example of a process flow 600 that supports a transparent display with a two-way viewing angle. The process flow 600 may be performed by aspects of the wireless communications system 100, such as a UE 115 or a network entity 105 as described with reference to FIG. 1. Additionally, or alternatively, any device with a transparent or semi-transparent screen and a pixel configuration 200 as described with reference to FIG. 2 may perform one or more operations of the process flow 600. In the following description of the process flow 600, some operations may be omitted from the process flow 600, and other operations may be added to the process flow 600. Further, although some operations or signaling may be shown to occur at different times for discussion purposes, these operations may occur at the same time.

At 605, a device with a transparent or semi-transparent screen may display a first image in a first direction in accordance with a first state of a set of switchable mirrors and a first state of a PDLC. For example, the device may display the first image in the first direction in accordance with a first emission of an OLED in the first direction, the set of switchable mirrors being in a first transparent state, and the PDLC being in an opaque state.

At 610, the device may switch the states of the set of switchable mirrors and the PDLC. For example, the device may switch the states in accordance with a display frequency for the transparent display. In some implementations, at 615, the device may change the voltages applied to the set of switchable mirrors and the PDLC to switch the states. For example, the device may switch the set of switchable mirrors from the first transparent state to a mirrored state and may switch the PDLC from the opaque state to a second transparent state.

At 620, the device may display a second image in a second direction in accordance with a second state of the set of switchable mirrors and a second state of the PDLC. For example, the device may display the second image in the second direction different from the first direction in accordance with a second emission of the OLED in the first direction and a reflection of the second emission according to the set of switchable mirrors being in the mirrored state and the PDLC being in the second transparent state.

At 625, the device may again switch the states of the set of switchable mirrors and the PDLC. For example, the device may switch the states in accordance with the display frequency for the transparent display. In some implementations, at 630, the device may change the voltages applied to the set of switchable mirrors and the PDLC to switch the states. For example, the device may switch the set of switchable mirrors from the mirrored state back to the first transparent state and may switch the PDLC from the second transparent state back to the opaque state. The device may repeat the operations of the process flow 600 in accordance with the display frequency to display both the first image in the first direction and the second image in the second direction via the transparent or semi-transparent screen.

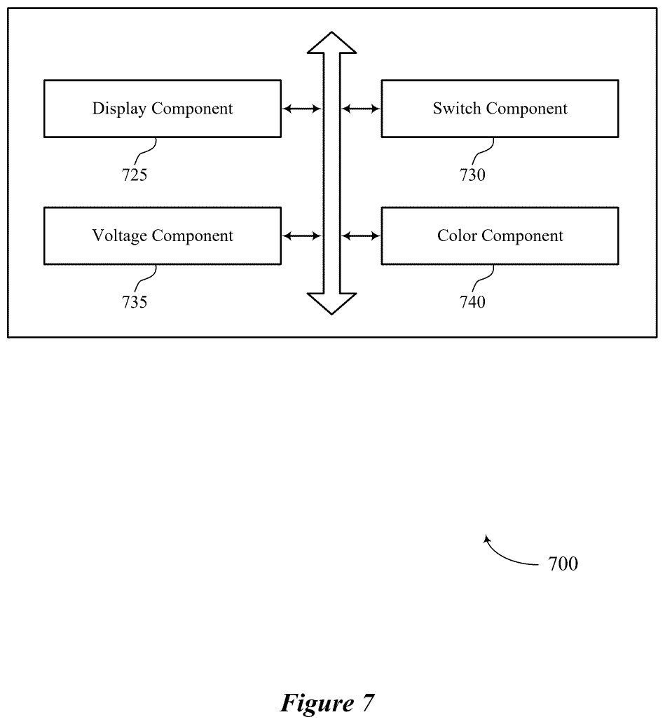

FIG. 7 shows a block diagram of an example display manager 700 that supports a transparent display with a two-way viewing angle. A device including a transparent or semi-transparent screen may include the display manager 700. In some implementations, the device may be an example of a UE 115 or a network entity 105 as described with reference to FIG. 1. The device may include one or more chips, systems-on-a-chip (SoCs), chipsets, packages, components, or devices that individually or collectively constitute or include a processing system. The processing system may interface with other components of the device and may generally process information (such as inputs or signals) received from such other components and output information (such as outputs or signals) to such other components. In some aspects, an example chip may include a processing system, a first interface to output or transmit information and a second interface to receive or obtain information. For example, the first interface may refer to an interface between the processing system of the chip and a transmission component, such that the device may transmit the information output from the chip. The second interface may refer to an interface between the processing system of the chip and a reception component, such that the device may receive information that is passed to the processing system. In some implementations, the first interface also may obtain information, such as from the transmission component, and the second interface also may output information, such as to the reception component.

The processing system of the device may include processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor” or “the processor circuitry”). One or more of the processors may be individually or collectively configurable or configured to perform various functions or operations described herein. The processing system may further include memory circuitry in the form of one or more memory devices, memory blocks, memory elements, or other discrete gate or transistor logic or circuitry, each of which may include tangible storage media such as random-access memory (RAM) or read-only (ROM), or combinations thereof (all of which may be generally referred to herein individually as “memories” or collectively as “the memory” or “the memory circuitry”). One or more of the memories may be coupled with one or more of the processors and may individually or collectively store processor-executable code that, when executed by one or more of the processors, may configure one or more of the processors to perform various functions or operations described herein. Additionally, or alternatively, in some implementations, one or more of the processors may be configured to perform various functions or operations described herein without requiring configuration by software. The processing system may further include or be coupled with one or more modems (such as a Wi-Fi (such as IEEE compliant) modem or a cellular (such as 3GPP 4G LTE, 5G, or 6G compliant) modem). In some implementations, one or more processors of the processing system include or implement one or more of the modems. The processing system may further include or be coupled with multiple radios (collectively “the radio”), multiple radio frequency (RF) chains, or multiple transceivers, each of which may in turn be coupled with one or more of multiple antennas. In some implementations, one or more processors of the processing system include or implement one or more of the radios, RF chains, or transceivers.

In some implementations, the device may further include a user interface (UI) (such as a touchscreen or keypad), a display, or both, where the display may be integrated with the UI to form a touchscreen display that is coupled with the processing system. The display may be an example of a transparent or semi-transparent display. In some implementations, the device may further include one or more sensors such as, for example, one or more inertial sensors, accelerometers, temperature sensors, pressure sensors, or altitude sensors, which are coupled with the processing system.

The display manager 700 of the device may include a display component 725, a switch component 730, a voltage component 735, a color component 740, or any combination thereof. Portions of one or more of the display component 725, the switch component 730, the voltage component 735, and the color component 740 may be implemented at least in part in hardware or firmware. For example, one or more of the display component 725, the switch component 730, the voltage component 735, and the color component 740 may be implemented at least in part by at least a processor or a modem. In some implementations, portions of one or more of the display component 725, the switch component 730, the voltage component 735, and the color component 740 may be implemented at least in part by a processor and software in the form of processor-executable code stored in memory.

The display component 725 is capable of, configured to, or operable to support a means for displaying a first color in a first direction in accordance with a first emission of an OLED in the first direction, a set of switchable mirrors being in a first transparent state, and a PDLC material being in an opaque state. In some implementations, the display component 725 is capable of, configured to, or operable to support a means for displaying a second color in a second direction different from the first direction in accordance with a second emission of the OLED in the first direction and a reflection of the second emission according to the set of switchable mirrors being in a mirrored state and the PDLC material being in a second transparent state.

In some implementations, the set of switchable mirrors switches between the first transparent state and the mirrored state according to a display frequency. In some such implementations, the PDLC material switches between the opaque state and the second transparent state according to the display frequency. For example, in some implementations, the switch component 730 is capable of, configured to, or operable to support a means for switching the set of switchable mirrors from the first transparent state to the mirrored state, from the mirrored state to the first transparent state, or both. Additionally, or alternatively, in some implementations, the switch component 730 is capable of, configured to, or operable to support a means for switching the PDLC material from the opaque state to the second transparent state, from the second transparent state to the opaque state, or both.

In some implementations, the voltage component 735 is capable of, configured to, or operable to support a means for applying a first voltage to the set of switchable mirrors, where the set of switchable mirrors is switched to the first transparent state in accordance with the first voltage. In some implementations, the voltage component 735 is capable of, configured to, or operable to support a means for applying a second voltage to the set of switchable mirrors, where the set of switchable mirrors is switched to the mirrored state in accordance with the second voltage. In some implementations, the voltage component 735 is capable of, configured to, or operable to support a means for applying a third voltage to the PDLC material, where the PDLC material is switched to the opaque state in accordance with the third voltage. In some implementations, the voltage component 735 is capable of, configured to, or operable to support a means for applying a fourth voltage to the PDLC material, where the PDLC material is switched to the second transparent state in accordance with the fourth voltage.

In some implementations, the color component 740 is capable of, configured to, or operable to support a means for applying a fifth voltage to a set of sub-pixels of the OLED, where the first color is displayed in accordance with the fifth voltage. In some such implementations, the color component 740 is capable of, configured to, or operable to support a means for applying a sixth voltage to the set of sub-pixels of the OLED, where the second color is displayed in accordance with the sixth voltage.

In some implementations, the set of switchable mirrors includes a first switchable mirror and a second switchable mirror. In some implementations, the PDLC material is located between the first switchable mirror and the second switchable mirror. In some implementations, the first color and the second color are displayed via a set of sub-pixels of the OLED. In some implementations, the PDLC material is perpendicular to the OLED and bisects an angle between the first switchable mirror and the second switchable mirror.

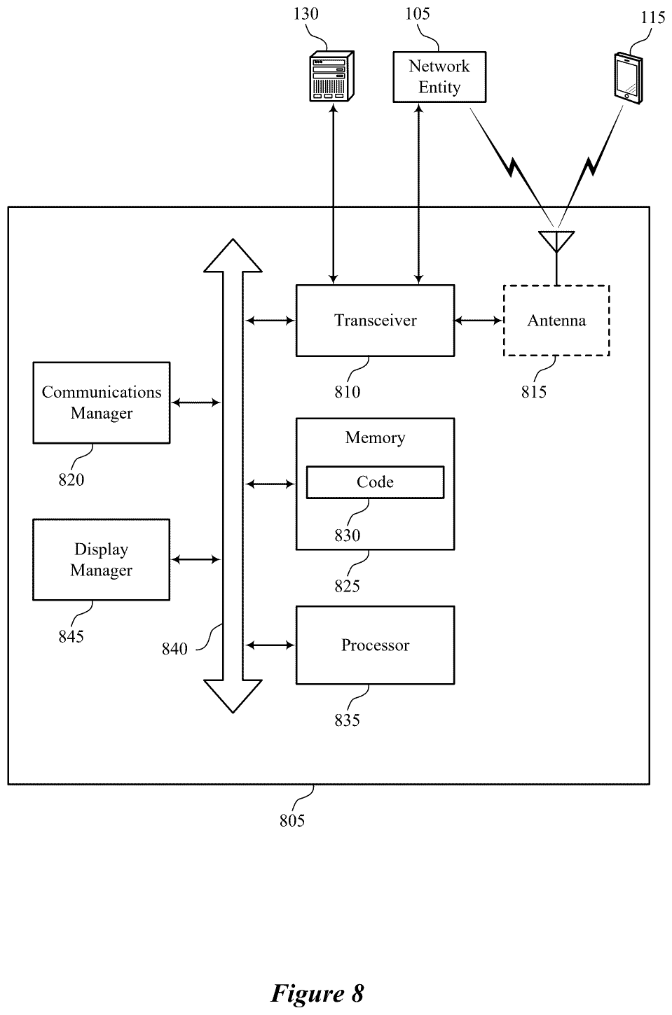

FIG. 8 shows a diagram of a system including an example device 805 that supports a transparent display with a two-way viewing angle. The device 805 may communicate with one or more network entities 105, one or more UEs 115, or any combination thereof, which may include communications over one or more wired interfaces, over one or more wireless interfaces, or any combination thereof. The device 805 may include components that support outputting and obtaining communications, such as a communications manager 820, a transceiver 810, one or more antennas 815, at least one memory 825, code 830, and at least one processor 835. The device 805 may additionally include components that support displaying contents, such as a display manager 845, the at least one memory 825, the code 830, and the at least one processor 835. These components may be in electronic communication or otherwise coupled (such as operatively, communicatively, functionally, electronically, electrically) via one or more buses (such as a bus 840).

The transceiver 810 may support bi-directional communications via wired links, wireless links, or both as described herein. In some implementations, the transceiver 810 may include a wired transceiver and may communicate bi-directionally with another wired transceiver. Additionally, or alternatively, in some implementations, the transceiver 810 may include a wireless transceiver and may communicate bi-directionally with another wireless transceiver. In some implementations, the device 805 may include one or more antennas 815, which may be capable of transmitting or receiving wireless transmissions (such as concurrently). The transceiver 810 also may include a modem to modulate signals, to provide the modulated signals for transmission (such as by one or more antennas 815 or by a wired transmitter), to receive modulated signals (such as from one or more antennas 815 or from a wired receiver), and to demodulate signals. In some implementations, the transceiver 810 may include one or more interfaces, such as one or more interfaces coupled with the one or more antennas 815 that are configured to support various receiving or obtaining operations, or one or more interfaces coupled with the one or more antennas 815 that are configured to support various transmitting or outputting operations, or a combination thereof. In some implementations, the transceiver 810 may include or be configured for coupling with one or more processors or one or more memory components that are operable to perform or support operations in accordance with received or obtained information or signals, or to generate information or other signals for transmission or other outputting, or any combination thereof. In some implementations, the transceiver 810, or the transceiver 810 and the one or more antennas 815, or the transceiver 810 and the one or more antennas 815 and one or more processors or one or more memory components (such as the at least one processor 835, the at least one memory 825, or both), may be included in a chip or chip assembly that is installed in the device 805. In some implementations, the transceiver 810 may be operable to support communications via one or more communications links (such as communication link(s) 125, backhaul communication link(s) 120, a midhaul communication link 162, a fronthaul communication link 168).

The at least one memory 825 may include RAM, ROM, or any combination thereof. The at least one memory 825 may store computer-readable, computer-executable, or processor-executable code, such as the code 830. The code 830 may include instructions that, when executed by one or more of the at least one processor 835, cause the device 805 to perform various functions described herein. The code 830 may be stored in a non-transitory computer-readable medium such as system memory or another type of memory. In some implementations, the code 830 may not be directly executable by a processor of the at least one processor 835 but may cause a computer (such as when compiled and executed) to perform functions described herein. In some implementations, the at least one memory 825 may include, among other things, a basic I/O system (BIOS) which may control basic hardware or software operation such as the interaction with peripheral components or devices. In some implementations, the at least one processor 835 may include multiple processors and the at least one memory 825 may include multiple memories. One or more of the multiple processors may be coupled with one or more of the multiple memories which may, individually or collectively, be configured to perform various functions described herein (such as, part of a processing system, a memory system, or both).

The at least one processor 835 may include an intelligent hardware device (such as a general-purpose processor, a DSP, an ASIC, a CPU, an FPGA, a microcontroller, a programmable logic device, discrete gate or transistor logic, a discrete hardware component, or any combination thereof). In some implementations, the at least one processor 835 may be configured to operate a memory array using a memory controller. In some other implementations, a memory controller may be integrated into one or more of the at least one processor 835. The at least one processor 835 may be configured to execute computer-readable instructions stored in a memory (such as one or more of the at least one memory 825) to cause the device 805 to perform various functions (such as functions or tasks supporting network slice feasibility assessment for a latency-based SLA). For example, the device 805 or a component of the device 805 may include at least one processor 835 and at least one memory 825 coupled with one or more of the at least one processor 835, the at least one processor 835 and the at least one memory 825 configured to perform various functions described herein. The at least one processor 835 may be an example of a cloud-computing platform (such as one or more physical nodes and supporting software such as operating systems, virtual machines, or container instances) that may host the functions (such as by executing code 830) to perform the functions of the device 805. The at least one processor 835 may be any one or more suitable processors capable of executing scripts or instructions of one or more software programs stored in the device 805 (such as within one or more of the at least one memory 825). In some implementations, the at least one processor 835 may include multiple processors and the at least one memory 825 may include multiple memories. One or more of the multiple processors may be coupled with one or more of the multiple memories, which may, individually or collectively, be configured to perform various functions herein.

In some implementations, the at least one processor 835 may be a component of a processing system, which may refer to a system (such as a series) of machines, circuitry (including, for example, one or both of processor circuitry (which may include the at least one processor 835) and memory circuitry (which may include the at least one memory 825)), or components, that receives or obtains inputs and processes the inputs to produce, generate, or obtain a set of outputs. The processing system may be configured to perform one or more of the functions described herein. For example, the at least one processor 835 or a processing system including the at least one processor 835 may be configured to, configurable to, or operable to cause the device 805 to perform one or more of the functions described herein. Further, as described herein, being “configured to,” being “configurable to,” and being “operable to” may be used interchangeably and may be associated with a capability, when executing code stored in the at least one memory 825 or otherwise, to perform one or more of the functions described herein.

In some implementations, a processing system of the device 805 may refer to a system including the various other components or subcomponents of the device 805, such as the at least one processor 835, or the transceiver 810, or the communications manager 820, or the display manager 845, or other components or combinations of components of the device 805. The processing system of the device 805 may interface with other components of the device 805 and may process information received from other components (such as inputs or signals) or output information to other components. For example, a chip or modem of the device 805 may include a processing system and one or more interfaces to output information, or to obtain information, or both.

The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 805 may transmit information output from the chip or modem. Additionally, or alternatively, in some implementations, the one or more interfaces may refer to an interface between the processing system of the chip or modem and a receiver, such that the device 805 may obtain information or signal inputs, and the information may be passed to the processing system. A person having ordinary skill in the art will readily recognize that a first interface also may obtain information or signal inputs, and a second interface also may output information or signal outputs.

The device 805 may include one or more chips, SoCs, chipsets, packages or devices that individually or collectively constitute or include a processing system. The processing system includes processor (or “processing”) circuitry in the form of one or multiple processors, microprocessors, processing units (such as CPUs, GPUs, or DSPs), processing blocks, ASIC, programmable logic devices (such as FPGAs), or other discrete gate or transistor logic or circuitry (all of which may be generally referred to herein individually as “processors” or collectively as “the processor” or “the processor circuitry”). One or more of the processors may be individually or collectively configurable or configured to perform various functions or operations described herein. The processing system may further include memory circuitry in the form of one or more memory devices, memory blocks, memory elements, or other discrete gate or transistor logic or circuitry, each of which may include tangible storage media such as RAM or ROM, or combinations thereof (all of which may be generally referred to herein individually as “memories” or collectively as “the memory” or “the memory circuitry”). One or more of the memories may be coupled with one or more of the processors and may individually or collectively store processor-executable code that, when executed by one or more of the processors, may configure one or more of the processors to perform various functions or operations described herein. Additionally, or alternatively, in some implementations, one or more of the processors may be configured to perform various functions or operations described herein without requiring configuration by software. The processing system may further include or be coupled with one or more modems (such as a Wi-Fi (such as IEEE compliant) modem or a cellular (such as 3GPP 4G LTE, 5G, or 6G compliant) modem). In some implementations, one or more processors of the processing system include or implement one or more of the modems. The processing system may further include or be coupled with multiple radios (collectively “the radio”), multiple RF chains, or multiple transceivers, each of which may in turn be coupled with one or more of multiple antennas. In some implementations, one or more processors of the processing system include or implement one or more of the radios, RF chains, or transceivers.

In some implementations, a bus 840 may support communications of (such as within) a protocol layer of a protocol stack. In some implementations, a bus 840 may support communications associated with a logical channel of a protocol stack (such as between protocol layers of a protocol stack), which may include communications performed within a component of the device 805, or between different components of the device 805 that may be co-located or located in different locations (such as where the device 805 may refer to a system in which one or more of the communications manager 820, the display manager 845, the transceiver 810, the at least one memory 825, the code 830, and the at least one processor 835 may be located in one of the different components or divided between different components).

In some implementations, the communications manager 820 may manage aspects of communications with a core network 130 (such as via one or more wired or wireless backhaul links). For example, the communications manager 820 may manage the transfer of data communications for client devices, such as one or more UEs 115. In some implementations, the communications manager 820 may manage communications with one or more other network entities 105, and may include a controller or scheduler for controlling communications with UEs 115 (such as in cooperation with the one or more other network devices). In some implementations, the communications manager 820 may support an X2 interface within an LTE/LTE-A wireless communications network technology to provide communication between network entities 105.

In some implementations, the display manager 845 may include a controller or other processing system that may control a set of pixels (such as OLED pixels or other types of pixels configured to emit light) for displaying images. The display manager 845 may be capable of, configured to, or operable to support a means for displaying a first color in a first direction in accordance with a first emission of an OLED in the first direction, a set of switchable mirrors being in a first transparent state, and a PDLC material being in an opaque state. In some implementations, the display manager 845 may be capable of, configured to, or operable to support a means for displaying a second color in a second direction different from the first direction in accordance with a second emission of the OLED in the first direction and a reflection of the second emission according to the set of switchable mirrors being in a mirrored state and the PDLC material being in a second transparent state.

In some implementations, the communications manager 820 may be configured to perform various operations (such as receiving, obtaining, monitoring, outputting, transmitting) using or otherwise in cooperation with the transceiver 810, the one or more antennas 815 (where applicable), or any combination thereof. Although the communications manager 820 is illustrated as a separate component, in some implementations, one or more functions described with reference to the communications manager 820 may be supported by or performed by the transceiver 810, one or more of the at least one processor 835, one or more of the at least one memory 825, the code 830, or any combination thereof (such as by a processing system including at least a portion of the at least one processor 835, the at least one memory 825, the code 830, or any combination thereof). For example, the code 830 may include instructions executable by one or more of the at least one processor 835 to cause the device 805 to perform various operations described herein, or the at least one processor 835 and the at least one memory 825 may be otherwise configured to, individually or collectively, perform or support such operations. Similarly, although the display manager 845 is illustrated as a separate component, in some implementations, one or more functions described with reference to the display manager 845 may be supported by or performed by one or more of the at least one processor 835, one or more of the at least one memory 825, the code 830, or any combination thereof (such as by a processing system including at least a portion of the at least one processor 835, the at least one memory 825, the code 830, or any combination thereof). For example, the code 830 may include instructions executable by one or more of the at least one processor 835 to cause the device 805 to perform various operations described herein with reference to the display manager 845, or the at least one processor 835 and the at least one memory 825 may be otherwise configured to, individually or collectively, perform or support such operations.

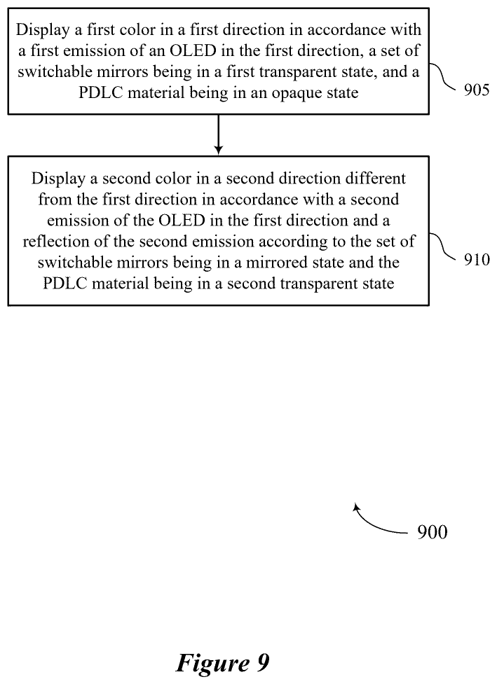

FIG. 9 shows a flowchart illustrating a method 900 that supports a transparent display with a two-way viewing angle. The operations of the method 900 may be implemented by a device with a transparent or semi-transparent display or its components as described herein. For example, the operations of the method 900 may be performed by a device as described with reference to FIGS. 6-8. In some implementations, the device may be an example of a UE 115 or a network entity 105 as described with reference to FIG. 1. In some aspects, the device may execute a set of instructions to control the functional elements of the device to perform the described functions. Additionally, or alternatively, the device may perform aspects of the described functions using special-purpose hardware.

At 905, the method may include displaying a first color in a first direction in accordance with a first emission of an OLED in the first direction, a set of switchable mirrors being in a first transparent state, and a PDLC material being in an opaque state. The operations of 905 may be performed in accordance with examples as disclosed herein. In some implementations, aspects of the operations of 905 may be performed by a display component 725 as described with reference to FIG. 7.

At 910, the method may include displaying a second color in a second direction different from the first direction in accordance with a second emission of the OLED in the first direction and a reflection of the second emission according to the set of switchable mirrors being in a mirrored state and the PDLC material being in a second transparent state. The operations of 910 may be performed in accordance with examples as disclosed herein. In some implementations, aspects of the operations of 910 may be performed by a display component 725 as described with reference to FIG. 7.

The following provides an overview of some aspects of the present disclosure:

Aspect 1: A device, including a processing system that includes processor circuitry and memory circuitry that stores code, the processing system configured to cause the device to display a first color in a first direction in accordance with a first emission of an OLED in the first direction, a set of switchable mirrors being in a first transparent state, and a PDLC material being in an opaque state, and display a second color in a second direction different from the first direction in accordance with a second emission of the OLED in the first direction and a reflection of the second emission according to the set of switchable mirrors being in a mirrored state and the PDLC material being in a second transparent state.

Aspect 2: The device of aspect 1, where the set of switchable mirrors switches between the first transparent state and the mirrored state according to a display frequency, and the PDLC material switches between the opaque state and the second transparent state according to the display frequency.

Aspect 3: The device of either of aspects 1 or 2, where the processing system is further configured to cause the device to apply a first voltage to the set of switchable mirrors, where the set of switchable mirrors is switched to the first transparent state in accordance with the first voltage.

Aspect 4: The device of any of aspects 1-3, where the processing system is further configured to cause the device to apply a second voltage to the set of switchable mirrors, where the set of switchable mirrors is switched to the mirrored state in accordance with the second voltage.

Aspect 5: The device of any of aspects 1-4, where the processing system is further configured to cause the device to apply a third voltage to the PDLC material, where the PDLC material is switched to the opaque state in accordance with the third voltage.

Aspect 6: The device of any of aspects 1-5, where the processing system is further configured to cause the device to apply a fourth voltage to the PDLC material, where the PDLC material is switched to the second transparent state in accordance with the fourth voltage.

Aspect 7: The device of any of aspects 1-6, where the processing system is further configured to cause the device to apply a fifth voltage to a set of sub-pixels of the OLED, where the first color is displayed in accordance with the fifth voltage, and apply a sixth voltage to the set of sub-pixels of the OLED, where the second color is displayed in accordance with the sixth voltage.

Aspect 8: The device of any of aspects 1-7, where the set of switchable mirrors includes a first switchable mirror and a second switchable mirror, and the PDLC material is located between the first switchable mirror and the second switchable mirror.

Aspect 9: The device of aspect 8, where the first color and the second color are displayed via a set of sub-pixels of the OLED, and the PDLC material is perpendicular to the OLED and bisects an angle between the first switchable mirror and the second switchable mirror.

Aspect 10: A method, including displaying a first color in a first direction in accordance with a first emission of an OLED in the first direction, a set of switchable mirrors being in a first transparent state, and a PDLC material being in an opaque state, and displaying a second color in a second direction different from the first direction in accordance with a second emission of the OLED in the first direction and a reflection of the second emission according to the set of switchable mirrors being in a mirrored state and the PDLC material being in a second transparent state.

Aspect 11: The method of aspect 10, where the set of switchable mirrors switches between the first transparent state and the mirrored state according to a display frequency, and the PDLC material switches between the opaque state and the second transparent state according to the display frequency.

Aspect 12: The method of either of aspects 10 or 11, further including applying a first voltage to the set of switchable mirrors, where the set of switchable mirrors is switched to the first transparent state in accordance with the first voltage.

Aspect 13: The method of any of aspects 10-12, further including applying a second voltage to the set of switchable mirrors, where the set of switchable mirrors is switched to the mirrored state in accordance with the second voltage.

Aspect 14: The method of any of aspects 10-13, further including applying a third voltage to the PDLC material, where the PDLC material is switched to the opaque state in accordance with the third voltage.

Aspect 15: The method of any of aspects 10-14, further including applying a fourth voltage to the PDLC material, where the PDLC material is switched to the second transparent state in accordance with the fourth voltage.

Aspect 16: The method of any of aspects 10-15, further including applying a fifth voltage to a set of sub-pixels of the OLED, where the first color is displayed in accordance with the fifth voltage, and applying a sixth voltage to the set of sub-pixels of the OLED, where the second color is displayed in accordance with the sixth voltage.

Aspect 17: The method of any of aspects 10-16, where the set of switchable mirrors includes a first switchable mirror and a second switchable mirror, and the PDLC material is located between the first switchable mirror and the second switchable mirror.

Aspect 18: The method of aspect 17, where the first color and the second color are displayed via a set of sub-pixels of the OLED, and the PDLC material is perpendicular to the OLED and bisects an angle between the first switchable mirror and the second switchable mirror.

Aspect 19: An apparatus, including means for displaying a first color in a first direction in accordance with a first emission of an OLED in the first direction, a set of switchable mirrors being in a first transparent state, and a PDLC material being in an opaque state, and means for displaying a second color in a second direction different from the first direction in accordance with a second emission of the OLED in the first direction and a reflection of the second emission according to the set of switchable mirrors being in a mirrored state and the PDLC material being in a second transparent state.

Aspect 20: The apparatus of aspect 19, where the set of switchable mirrors switches between the first transparent state and the mirrored state according to a display frequency, and the PDLC material switches between the opaque state and the second transparent state according to the display frequency.

Aspect 21: The apparatus of either of aspects 19 or 20, further including means for applying a first voltage to the set of switchable mirrors, where the set of switchable mirrors is switched to the first transparent state in accordance with the first voltage.

Aspect 22: The apparatus of any of aspects 19-21, further including means for applying a second voltage to the set of switchable mirrors, where the set of switchable mirrors is switched to the mirrored state in accordance with the second voltage.

Aspect 23: The apparatus of any of aspects 19-22, further including means for applying a third voltage to the PDLC material, where the PDLC material is switched to the opaque state in accordance with the third voltage.

Aspect 24: The apparatus of any of aspects 19-23, further including means for applying a fourth voltage to the PDLC material, where the PDLC material is switched to the second transparent state in accordance with the fourth voltage.

Aspect 25: The apparatus of any of aspects 19-24, further including means for applying a fifth voltage to a set of sub-pixels of the OLED, where the first color is displayed in accordance with the fifth voltage, and means for applying a sixth voltage to the set of sub-pixels of the OLED, where the second color is displayed in accordance with the sixth voltage.

Aspect 26: The apparatus of any of aspects 19-25, where the set of switchable mirrors includes a first switchable mirror and a second switchable mirror, and the PDLC material is located between the first switchable mirror and the second switchable mirror.

Aspect 27: The apparatus of aspect 26, where the first color and the second color are displayed via a set of sub-pixels of the OLED, and the PDLC material is perpendicular to the OLED and bisects an angle between the first switchable mirror and the second switchable mirror.

Aspect 28: A pixel structure, including a first substrate parallel to a second substrate, an OLED between the first substrate and the second substrate and oriented for display in a first direction towards the second substrate, a first switchable mirror oriented at a first angle to the OLED and extending in the first direction, a second switchable mirror oriented at a second angle to the first substrate and extending in the first direction, where the first switchable mirror and the second switchable mirror converge at a third angle, and a PDLC material oriented perpendicular to the OLED and extending in the first direction, where the PDLC material bisects the third angle between the first switchable mirror and the second switchable mirror.

Aspect 29: The pixel structure of aspect 28, further including a shared conductive line coupled with the first switchable mirror, the second switchable mirror, and the PDLC material.

Aspect 30: The pixel structure of aspect 28, further including a first conductive line coupled with the first switchable mirror and the second switchable mirror, and a second conductive line coupled with the PDLC material.

Aspect 31: The pixel structure of any of aspects 28-30, where the first switchable mirror and the second switchable mirror support a transparent state and a mirror stated in accordance with a voltage applied to the first switchable mirror and the second switchable mirror.

Aspect 32: The pixel structure of any of aspects 28-31, where the PDLC material supports a transparent state and an opaque state in accordance with a voltage applied to the PDLC material.

Aspect 33: The pixel structure of any of aspects 28-32, where the OLED includes a set of sub-pixels corresponding to a set of respective colors for emission.

Aspect 34: The pixel structure of any of aspects 28-33, where the first substrate and the second substrate are glass.

As used herein, the term “determine” or “determining” encompasses a wide variety of actions and, therefore, “determining” can include calculating, computing, processing, deriving, investigating, looking up (such as via looking up in a table, a database or another data structure), inferring, ascertaining, and the like. Also, “determining” can include receiving (such as receiving information), accessing (such as accessing data stored in memory) and the like. Also, “determining” can include resolving, selecting, choosing, establishing and other such similar actions.

As used herein, a phrase referring to “at least one of” a list of items refers to any combination of those items, including single members. As an example, “at least one of: a, b, or c” is intended to cover: a, b, c, a-b, a-c, b-c, and a-b-c.

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented using hardware or software depends upon the particular application and design constraints imposed on the overall system.

The hardware and data processing apparatus used to implement the various illustrative logics, logical blocks, modules and circuits described in connection with the aspects disclosed herein may be implemented or performed using a general purpose single-or multi-chip processor, a digital signal processor (DSP), an application specific integrated circuit (ASIC), a graphics processing unit (GPU), a neural processing unit (NPU), a field programmable gate array (FPGA) or other programmable logic device, discrete gate or transistor logic, discrete hardware components, or any combination thereof designed to perform the functions described herein. A general-purpose processor may be a microprocessor, or any processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented using hardware, digital electronic circuitry, computer software, firmware, including the structures disclosed in this specification and their structural equivalents thereof, or in any combination thereof. Implementations of the subject matter described in this specification also can be implemented as one or more computer programs, such as one or more modules of computer program instructions, encoded on a computer storage media for execution by, or to control the operation of, data processing apparatus.

If implemented in software, the functions may be stored on or transmitted using one or more instructions or code of a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one location to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and Blu-ray disc. Disks may reproduce data magnetically and discs may reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in some combinations and even initially claimed as such, one or more features from a claimed combination can be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some implementations, the actions recited in the claims can be performed in a different order and still achieve desirable results.

What is claimed is:

1. A device, comprising:
a processing system that includes processor circuitry and memory circuitry that stores code, the processing system configured to cause the device to:
display a first color in a first direction in accordance with a first emission of an organic light-emitting diode (OLED) in the first direction, a set of switchable mirrors being in a first transparent state, and a polymer dispersed liquid crystal (PDLC) material being in an opaque state; and
display a second color in a second direction different from the first direction in accordance with a second emission of the OLED in the first direction and a reflection of the second emission according to the set of switchable mirrors being in a mirrored state and the PDLC material being in a second transparent state.

2. The device of claim 1, wherein:
the set of switchable mirrors switches between the first transparent state and the mirrored state according to a display frequency; and
the PDLC material switches between the opaque state and the second transparent state according to the display frequency.

3. The device of claim 1, wherein the processing system is further configured to cause the device to:
apply a first voltage to the set of switchable mirrors, wherein the set of switchable mirrors is switched to the first transparent state in accordance with the first voltage.

4. The device of claim 1, wherein the processing system is further configured to cause the device to:
apply a second voltage to the set of switchable mirrors, wherein the set of switchable mirrors is switched to the mirrored state in accordance with the second voltage.

5. The device of claim 1, wherein the processing system is further configured to cause the device to:
apply a third voltage to the PDLC material, wherein the PDLC material is switched to the opaque state in accordance with the third voltage.

6. The device of claim 1, wherein the processing system is further configured to cause the device to:
apply a fourth voltage to the PDLC material, wherein the PDLC material is switched to the second transparent state in accordance with the fourth voltage.

7. The device of claim 1, wherein the processing system is further configured to cause the device to:
apply a fifth voltage to a set of sub-pixels of the OLED, wherein the first color is displayed in accordance with the fifth voltage; and
apply a sixth voltage to the set of sub-pixels of the OLED, wherein the second color is displayed in accordance with the sixth voltage.

8. The device of claim 1, wherein:
the set of switchable mirrors comprises a first switchable mirror and a second switchable mirror; and
the PDLC material is located between the first switchable mirror and the second switchable mirror.

9. The device of claim 8, wherein:
the first color and the second color are displayed via a set of sub-pixels of the OLED; and
the PDLC material is perpendicular to the OLED and bisects an angle between the first switchable mirror and the second switchable mirror.

10. A method, comprising:
displaying a first color in a first direction in accordance with a first emission of an organic light-emitting diode (OLED) in the first direction, a set of switchable mirrors being in a first transparent state, and a polymer dispersed liquid crystal (PDLC) material being in an opaque state; and
displaying a second color in a second direction different from the first direction in accordance with a second emission of the OLED in the first direction and a reflection of the second emission according to the set of switchable mirrors being in a mirrored state and the PDLC material being in a second transparent state.

11. The method of claim 10, wherein:
the set of switchable mirrors switches between the first transparent state and the mirrored state according to a display frequency; and
the PDLC material switches between the opaque state and the second transparent state according to the display frequency.

12. The method of claim 10, wherein:
the set of switchable mirrors comprises a first switchable mirror and a second switchable mirror; and
the PDLC material is located between the first switchable mirror and the second switchable mirror.

13. The method of claim 12, wherein:
the first color and the second color are displayed via a set of sub-pixels of the OLED; and
the PDLC material is perpendicular to the OLED and bisects an angle between the first switchable mirror and the second switchable mirror.

14. A pixel structure, comprising:
a first substrate parallel to a second substrate;
an organic light-emitting diode (OLED) between the first substrate and the second substrate and oriented for display in a first direction towards the second substrate;
a first switchable mirror oriented at a first angle to the OLED and extending in the first direction;
a second switchable mirror oriented at a second angle to the first substrate and extending in the first direction, wherein the first switchable mirror and the second switchable mirror converge at a third angle; and
a polymer dispersed liquid crystal (PDLC) material oriented perpendicular to the OLED and extending in the first direction, wherein the PDLC material bisects the third angle between the first switchable mirror and the second switchable mirror.

15. The pixel structure of claim 14, further comprising:
a shared conductive line coupled with the first switchable mirror, the second switchable mirror, and the PDLC material.

16. The pixel structure of claim 14, further comprising:
a first conductive line coupled with the first switchable mirror and the second switchable mirror; and
a second conductive line coupled with the PDLC material.

17. The pixel structure of claim 14, wherein the first switchable mirror and the second switchable mirror support a transparent state and a mirror stated in accordance with a voltage applied to the first switchable mirror and the second switchable mirror.

18. The pixel structure of claim 14, wherein the PDLC material supports a transparent state and an opaque state in accordance with a voltage applied to the PDLC material.

19. The pixel structure of claim 14, wherein the OLED comprises a set of sub-pixels corresponding to a set of respective colors for emission.

20. The pixel structure of claim 14, wherein the first substrate and the second substrate are glass.
